(19) United States
(12) Patent Application Publication
(10) Pub. No.: US 2015/0271915 A1
(43) Pub. Date: Sep. 24, 2015

(54) ENHANCED CHIP BOARD PACKAGE STRUCTURE

(71) Applicant: KINSUS INTERCONNECT TECHNOLOGY CORP., Taoyuan (TW)

(72) Inventors: Jun-Chung Hsu, Taoyuan County (TW); Bo-Yu Tseng, Hsinchu County (TW); Yu-Hsiang Sun, Taichung City (TW)

(73) Assignee: KINSUS INTERCONNECT TECHNOLOGY CORP., Taoyuan (TW)

(21) Appl. No.: 14/223,661

(22) Filed: Mar. 24, 2014

(51) Int. Cl. H05K 1/02; H05K 1/11; H05K 1/09

(52) U.S. Cl. CPC H05K 1/0271; H05K 1/0298; H05K 1/09; H05K 1/113

(57) ABSTRACT

An enhanced chip board package structure includes a chip board and a plurality of enhanced structures, which are formed in the blind openings of the non-effective region of the chip board. Each enhanced structure has an opening. The mechanical strength is reinforced by the enhanced structures without changing the whole thickness so as to overcome the problem of warping. Meanwhile, the three-dimensional stability is thus enhanced. The opening of the enhanced structure can be selectively filled with the filler such that the mechanical strength is further reinforced and the thermally conductive effect is greatly improved.

### BACKGROUND OF THE INVENTION

1. Field of the Invention

The present invention generally relates to a package structure, and more specifically to an enhanced chip board package provided with the enhanced in the non-effective region of the chip board.

2. The Prior Arts

Referring to FIG. 1, a chip board structure 100 in the prior arts includes at least one circuit board layer 20 and a second circuit layer 30. The second circuit layer 30 is formed on the upper surface of the uppermost circuit board layer 20. Each circuit board layer 20 includes a dielectric layer 21 and a first circuit layer 23. The first circuit layer 23 is embedded in the dielectric layer 21 and is exposed from the lower surface of the dielectric layer 21. The first circuit layer 23 includes a plurality of first circuit patterns 25 and a plurality of first connection pads 27, which are connected to each other (not shown). The lower surface of one circuit board layer 20 is connected to and stacked on the upper surface of another circuit board layer 20. As a result, the upper first circuit layer 23 is enclosed by the lower dielectric layer 21 and the upper first connection pad 27 is connected to the lower first connection pad 27 via the connection plug 29 formed in the hole of the dielectric layer 21.

The second circuit layer 30 is formed on the upper surface of the uppermost circuit board 20, and includes a plurality of second circuit patterns 31 and a plurality of second connection pads 33. The second connection pads 33 are connected to the corresponding connection plugs 29 so as to be electrically connected to the lower first circuit layer 23. The chip board 10 further includes a first solder mask 41 and a second solder mask 43. The first solder mask 41 is provided on the lower surface of the chip board 10 and covers the first circuit patterns 25 and part of the first connection pads 27. The second solder mask 43 is provided on the upper surface of the chip board 10 and covers the second circuit patterns 31 and part of the second connection pads 33. Each of the chip pins 75 of the chip 70 is soldered to the corresponding second connection pad 33 through the solder 65.

With the requirement of compact products, the chip package structure 100 becomes much thinner. Usually, the thickness of the chip package structure 100 is less than 300 μm. However, as the mechanical properties change, such as weaker stiffness, it is possible to cause the chip package structure 100 to warp. As a result, the reliability of the whole body is obviously deteriorated because the location of the soldering part is easily shifted and the circuit detached. Therefore, it needs an enhanced chip board package structure to improve the reliability, thereby overcoming the drawbacks in the prior arts.

### SUMMARY OF THE INVENTION

The primary object of the present invention is to provide an enhanced chip board package structure. The enhanced chip board package structure of the present invention generally includes a chip board and a plurality of enhanced structures. The enhanced structures are formed in the blind openings of the non-effective region of the chip board, and each enhanced structure has an opening. Without increasing the total thickness, the chip board is reinforced by the enhanced structure so as to solve the problem of weak mechanical strength and easy warping. Additionally, the opening is selectively filled with the filler.

Meanwhile, with the enhanced structures overcoming the issue of easy warping, the three-dimensional stability is greatly increased. The filler is selectively filled such that the mechanical strength is further reinforced and the thermally conductive effect is greatly improved.

### BRIEF DESCRIPTION OF THE DRAWINGS

The present invention can be understood in more detail by reading the subsequent detailed description in conjunction with the examples and references made to the accompanying drawings, wherein:

FIG. 1 is a cross sectional view of the chip board package structure of the prior arts;

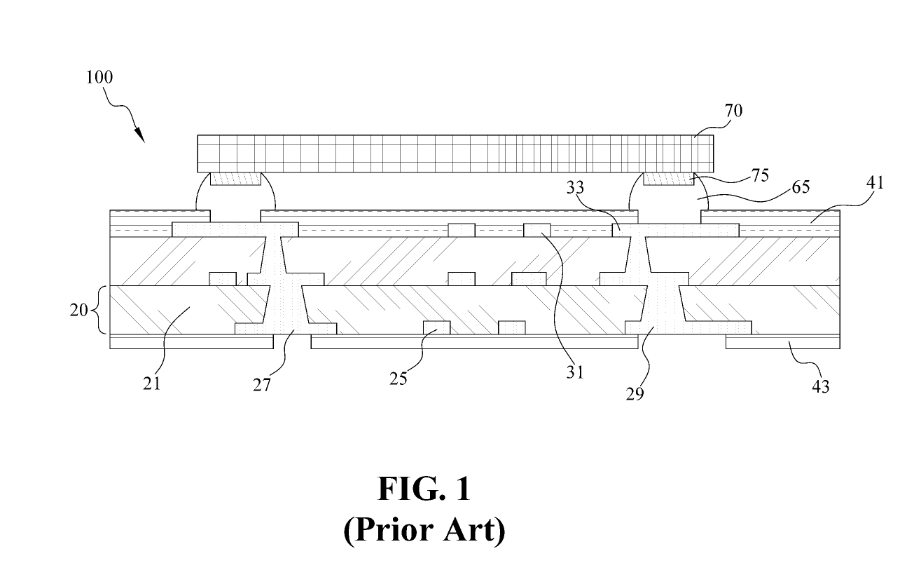

FIG. 2 is a cross sectional view illustrating the enhanced chip board package structure according to the present invention;

FIG. 3 is a bottom view of the enhanced chip board package structure according to the present invention;

FIG. 4A is an enlarged view showing the region (A) in FIG. 3 according to a first embodiment of the present invention; and

FIG. 4B is an enlarged view showing the region (A) in FIG. 3 according to a second embodiment of the present invention.

### DETAILED DESCRIPTION OF THE PREFERRED EMBODIMENTS

The present invention may be embodied in various forms and the details of the preferred embodiments of the present invention will be described in the subsequent content with reference to the accompanying drawings. The drawings (not to scale) show and depict only the preferred embodiments of the invention and shall not be considered as limitations to the scope of the present invention. Modifications of the shape of the present invention shall too be considered to be within the spirit of the present invention.

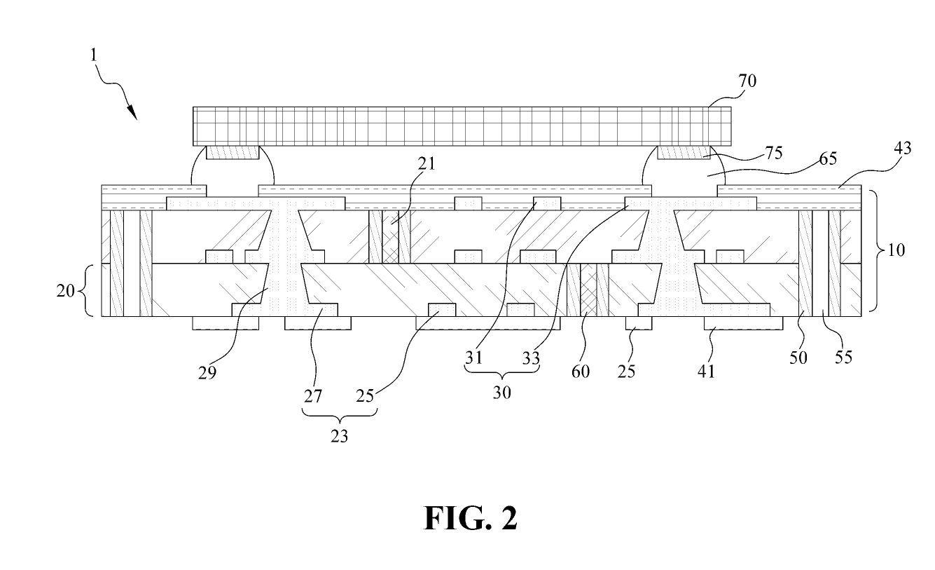

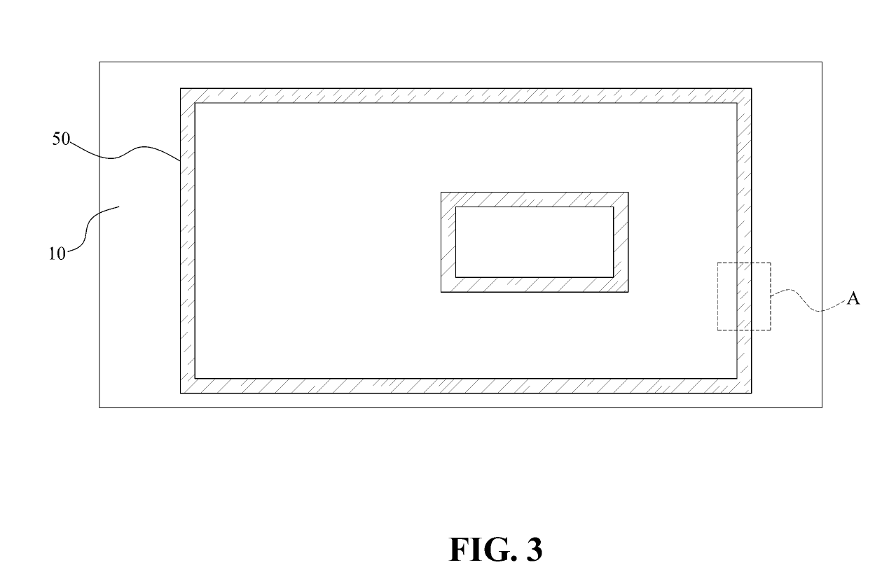

FIGS. 2 and 3 respectively show a cross sectional view and a top view of the enhanced chip board package structure according to the present invention. As shown in FIGS. 2 and 3, the enhanced chip board package structure 1 of the present invention generally includes a chip board 10 and a plurality of enhanced structures 50. The chip board 10 includes at least one circuit board layer 20 and a second circuit layer 30 formed on the uppermost circuit board layer 20. Each circuit board layer 20 includes a dielectric layer 21 and a first circuit layer 23 embedded in the dielectric layer 21 and exposed from the lower surface of the dielectric layer 21. The first circuit layer 23 includes a plurality of first circuit patterns 25 and a plurality of first connection pads 27, which are connected to each other (not shown). The upper surface of one circuit board layer 20 is stacked and in contact with the lower surface of another circuit board layer 20 such that the upper first circuit layer 23 is enclosed by the lower dielectric layer 21. The upper first connection pads 27 are connected to the lower first connection pads 27 through a plurality of connection plugs 29 formed in the holes of the dielectric layer 21.

The second circuit layer 30 is formed on the upper surface of the uppermost circuit board layer 20 and includes a plurality of second circuit patterns 31 and a plurality of second connection pads 33. The second connection pads 33 are connected to the corresponding connection plugs 29 so as to be electrically connected to the lower first circuit layer 23. Furthermore, the chip board 10 may include a first solder mask 41 and a second solder mask 43. The first solder mask 41 is provided on the lower surface of the chip board 10 and covers the first circuit patterns 25 and part of the first connection pads 27. The second solder mask 43 is provided on the upper surface of the chip board 10 and covers the second circuit patterns 31 and part of the second connection pads 33. The chip board has a thickness less than 300 μm.

The enhanced structures 50 are formed in the non-effective region of the chip board 10, such as the outer rim of the chip board 10 and/or the region connected to the chip 70. More specifically, the enhanced structures 50 fill up the blind holes of the non-effective region of the chip board 10. The blind holes are formed in at least one circuit board layer 20, or at least two circuit board layers 20. Each enhanced structures 50 has an opening 55. Additionally, the opening 55 of the enhanced structure 50 is selectively filled with the filler 60 to increase the thermally conductive effect or reinforce its mechanical strength. The filler 60 is preferably selected from a group consisting of at least one of copper, silver, gold, palladium, nickel, aluminum and graphite. Each chip pin 75 of the chip 70 is soldered to the corresponding second connection pad 33 through a solder 65.

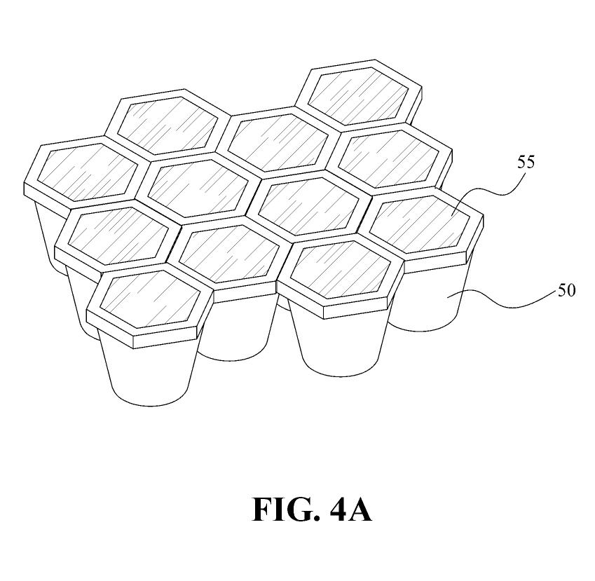

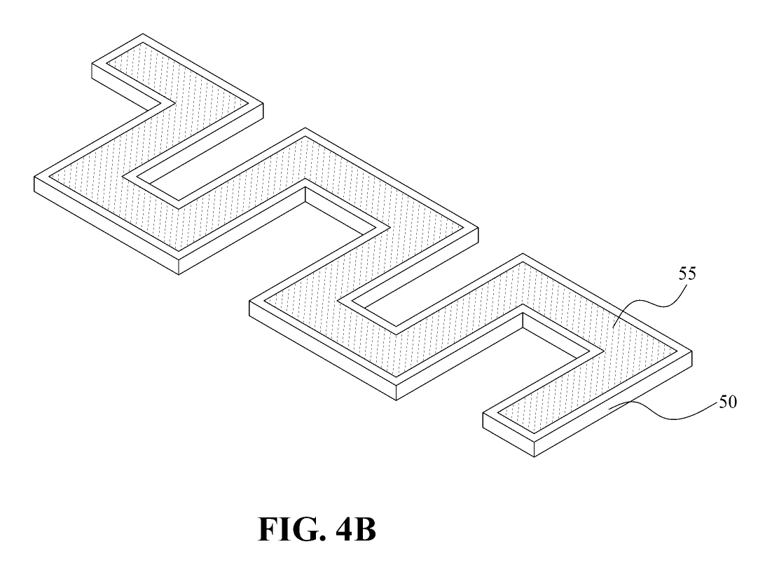

FIGS. 4A and 4B illustrate enlarged views of the region A in FIG. 3 according to the first and second embodiments of the present invention, respectively. As shown in FIG. 4A, the enhanced structure 50 is a hexagonal column, and has the hexagonal opening 55. The sidewalls of the enhanced structures 50 are stacked in a way of a honey comb. As shown in FIG. 4B, the enhanced structure 50 is a rectangular shape and has a rectangular opening. The openings 55 of the enhanced structures 50 are spatially communicated to each other and the sidewalls of the enhanced structures 50 are vertically arranged to each other to form a battlement structure.

One key feature of the present invention is that the enhanced structures formed in the blind holes of the non-effective region of the chip board are used to improve the problem of weak mechanical strength and to prevent warping, without increasing the total thickness. Meanwhile, the enhanced structures are hollow and can be further filled with the filler so as to the effect of thermal conduction and dissipation.

Although the present invention has been described with reference to the preferred embodiments, it will be understood that the invention is not limited to the details described thereof. Various substitutions and modifications have been suggested in the foregoing description, and others will occur to those of ordinary skill in the art. Therefore, all such substitutions and modifications are intended to be embraced within the scope of the invention as defined in the appended claims.

1-9. (canceled)

10. An enhanced chip board package structure, comprising:
a chip board having at least one non-effective region, the chip board including at least one circuit board, each of the at least one circuit board having a dielectric layer and a first circuit layer embedded in the dielectric layer and exposed from a lower surface of the dielectric layer, the first circuit layer having a plurality of first circuit patterns and a plurality of first connection pads;
a second circuit layer formed above the at least one circuit board, the second circuit layer having a plurality of second circuit patterns and a plurality of second connection pads, the second connection pads being connected to the first connection pads embedded in a top dielectric layer of the at least one circuit board by a plurality of connection plugs formed in the top dielectric layer;
a plurality of enhanced structures formed in the at least one non-effective region, each of the enhanced structures having an unfilled opening penetrating through at least one dielectric layer in the at least one circuit board;
wherein the non-effective region is located at an outer rim area of the chip board, an area outside of a region of the chip board connected to a chip, or both areas.

11. The enhanced chip board package structure as claimed in claim 10, wherein the chip board includes at least two circuit boards stacked together and the respective first connection pads of two adjacent circuit boards are connected by a plurality of connection plugs formed in the dielectric layer between the respective first connection pads.

12. The enhanced chip board package structure as claimed in claim 11, wherein at least one of the enhanced structures is formed through two connected adjacent dielectric layers with the unfilled opening penetrating through the two connected adjacent dielectric layers.

13. The enhanced chip board package structure as claimed in claim 10, wherein each of the enhanced structures is a hexagonal column with an unfilled opening of a hexagonal shape, and sidewalls of the enhanced structures are arranged in the form of a honey comb.

14. The enhanced chip board package structure as claimed in claim 10, wherein each of the enhanced structures is a rectangular shape with an unfilled rectangular opening, and the unfilled rectangular openings of the enhanced structures are spatially communicated to each other.

15. An enhanced chip board package structure, comprising:
a chip board having at least one non-effective region, the chip board including at least one circuit board, each of the at least one circuit board having a dielectric layer and a first circuit layer embedded in the dielectric layer and exposed from a lower surface of the dielectric layer, the first circuit layer having a plurality of first circuit patterns and a plurality of first connection pads;
a second circuit layer formed above the at least one circuit board, the second circuit layer having a plurality of second circuit patterns and a plurality of second connection pads, the second connection pads being connected to the first connection pads embedded in a top dielectric layer of the at least one circuit board by a plurality of connection plugs formed in the top dielectric layer;
a plurality of enhanced structures formed in the at least one non-effective region, at least one of the enhanced structures having an unfilled opening penetrating through at least one dielectric layer in the at least one circuit board;
wherein the non-effective region is located at an outer rim area of the chip board, an area outside of a region of the chip board connected to a chip, or both areas.

16. The enhanced chip board package structure as claimed in claim 15, wherein the chip board includes at least two circuit boards stacked together and the respective first circuit connection pads of two adjacent circuit boards are connected by a plurality of connection plugs formed in the dielectric layer between the respective first circuit connection pads.

17. The enhanced chip board package structure as claimed in claim 16, wherein at least one of the enhanced structures is formed through two connected adjacent dielectric layers.

18. The enhanced chip board package structure as claimed in claim 16, wherein at least one of the enhanced structures has an unfilled opening penetrating through two connected adjacent dielectric layers.

19. The enhanced chip board package structure as claimed in claim 15, wherein some of the enhanced structures are filled with fillers.

20. The enhanced chip board package structure as claimed in claim 19, wherein the filler is selected from a group consisting of at least one of copper, silver, gold, palladium, nickel, aluminum and graphite.

21. The enhanced chip board package structure as claimed in claim 15, wherein each of the enhanced structures is a hexagonal column, the unfilled opening has a hexagonal shape, and sidewalls of the enhanced structures are arranged in the form of a honey comb.
